(19) United States
(12) Patent Application Publication
(10) Pub. No.: US 2025/0364392 A1
(43) Pub. Date: Nov. 27, 2025

(54) HALF-BRIDGE MODULE HAVING PARALLEL SUPPLY LINES CONNECTED TO INSULATED TERMINAL PADS BETWEEN TWO STRIP PORTIONS AND TO ONE OF THE STRIP PORTIONS OF A CONDUCTOR PATH LAYER

(71) Applicant: Vitesco Technologies GmbH, Regensburg (DE)

(72) Inventor: Alexander Kuschel, Regensburg (DE)

(73) Assignee: Vitesco Technologies GmbH, Regensburg (DE)

(21) Appl. No.: 18/869,018

(22) PCT Filed: May 23, 2023
(86) PCT No.: PCT/EP2023/063834

§ 371 Date: Aug. 13, 2025

(30) Foreign Application Priority Data
May 31, 2022 (DE) 10 2022 205 514.4

(51) Int. Cl. H01L 23/498; H01L 25/07

(52) U.S. Cl. CPC H01L 23/49844; H01L 23/49811; H01L 25/072

(57) ABSTRACT

Half-bridge module having parallel supply lines connected to insulated terminal pads between two strip portions and to one of the strip portions of a conductor path layer. A half-bridge module is equipped with a first power supply line, a second power supply line, and with a phase supply line and with a carrier. The carrier has a conductor path layer which has terminal pads in an intermediate portion which is located between a first and a second transistor strip portion of the conductor path layer. The terminal pads are in each case insulated peripherally in the conductor path layer. The first power supply line is connected to the terminal pads and leads away therefrom. The second power supply line is connected to at least one contact point within the second transistor strip portion and leads away therefrom. The phase supply line is connected to at least one contact point within the intermediate portion or the first transistor strip portion and leads away therefrom.

### CROSS-REFERENCE TO RELATED APPLICATIONS

This application claims priority to PCT Application PCT/EP2023/063834, filed May 23, 2023, which claims priority to German Patent Application No. DE 10 2022 205 514.4, filed May 31, 2022. The disclosures of the above applications are incorporated herein by reference.

### BACKGROUND OF THE INVENTION

Electrically powered vehicles have electric machines with windings which can be energized switchably. In order to achieve the required powers of often more than 100 KW, high currents of often more than 100 amperes and operating voltages of often more than 100 V, in particular 800V, are used. Power transistors that produce switching edges with a high current stroke in a short time are thus used for the switched energization of the windings. In particular, in order to achieve even shorter switching edges or higher slew rates of the transistors, extremely fast-switching transistors such as SiC transistors are used. A very low-induction circuit is required in order to be able to employ such fast-switching transistors effectively. Furthermore, in the case of fast-switching transistors, the signal transit times caused by the circuit need to be taken into account in order to reliably switch the transistors.

### SUMMARY OF THE INVENTION

It is an object of the invention to present an option by which high-power transistors may be interconnected to form half-bridges in a low-induction manner.

This object is achieved by the half-bridge module described. Further properties, features, and embodiments will become apparent from the description and the figures.

A half-bridge module with a first power supply line, a second power supply line, and a phase supply line is described. The supply lines may also be referred to as busbars. The half-bridge module moreover has a carrier which has a conductor path layer. The carrier may be formed with one or more layers. The conductor path layer is one side of the carrier and is not an embedded layer. The conductor path layer is an uncovered conductor path layer (i.e. is not covered by insulator layers of the carrier). The conductor path layer is designed as a structured, conductive layer and thus has surfaces which are not connected to one another via the conductor path layer. This structuring results in a layout.

The carrier or the conductor path layer is divided into three strips. The three strips may refer to the whole carrier or the conductor path layer, or to a region thereof. The strips are situated directly next to one another. The strips are a geometric division and are not necessarily an electrical subdivision with electrical separation from one another. The strips are therefore a geometric subdivision of a surface. The subdivision into strips does not involve a subdivision of the conductor path layer in the manner of conductor paths; for example, the electrical subdivision or the layout may deviate from this at least in portions. The strips include a first and a second strip portion, as well as an intermediate portion which is located between the two of them. The strips extend in the same longitudinal direction along their larger dimension. The carrier or the conductor path layer itself may also be configured, for example, as rectangular, wherein the longer side of the rectangle extends in the longitudinal direction. This direction is also referred to as the first longitudinal direction.

The first and the second strip portions are each designed to be populated with transistors or other semiconductors such that they are also referred to as transistor strip portions. Terminal pads are located in the intermediate portion as individual pads. The terminal pads are electrically insulated from the remaining, surrounding conductor path layer within the conductor path layer itself. The terminal pads are thus surrounded by a groove or a trough or a trench which extends through the whole thickness of the conductor path layer. The terminal pads are therefore surrounded by recesses in the conductor path layer which electrically separate the terminal pads within the conductor path layer. The terminal pads are insulated peripherally in the conductor path layer. If terminal pads are located at the edge of the carrier or conductor path layer, then the latter is also peripherally insulated where it is surrounded by the further conductor path layer. In the case of terminal pads located at the edge, the conductor path layer is partially insulated peripherally within the conductor path layer (and thus peripherally except for the region of the terminal pads which are situated at the edge), wherein terminal pads inside the conductor path layer are completely insulated peripherally. The geometric subdivision into the first strip portion and the intermediate portion differs from an electrical subdivision into surfaces which are located within these portions or from the layout which is located in the two portions. The geometric subdivision into the second strip portion, on the one hand, and the intermediate portion, on the other hand, may correspond to an electrical subdivision into surfaces which are located within these portions or correspond to the layout which electrically separates the (conductive) surface of the second strip portion from the (conductive) surfaces of the intermediate portion.

The first power supply line is connected to the terminal pads, for example by a direct mechanical fastening (soldered connection, welded connection, such as friction welded connection, sintering, screws, press-fit connection, . . . ). The supply line leads away from the terminal pads. As a result, the potential of a supply voltage is fed into the intermediate region of the conductor path layer, while the (two) further supply lines may be routed into the strip portions (or into a strip portion and the intermediate region) in order to be connected there to surfaces of the conductor path layer. By using terminal pads within the intermediate portion, it is therefore possible to mechanically connect all three supply lines to corresponding (in each case single or multiple) contact points of the conductor path layer, i.e. to the same conductive layer. Therefore, no additional layers are necessary because the supply line is fastened within the intermediate portion or be connected to the terminal pad present there.

In addition, the conductor path layout of the conductor path layer enables contact points for the supply lines, which are all situated in the conductor path layer (albeit in electrically separated regions or surfaces of the conductor path layer). The result is a negative and cost-effective connection technology which moreover enables short signal transit times. The three supply lines may be connected in the same way to the relevant contact points of the conductor path layer such that the supply lines may also be designed with low inductance and low interference.

Flat conductors, such as metal sheets or the like, which extend away from the conductor path layer are suitable as supply lines. For example, the two power supply lines may be designed to be situated closely next to each other, wherein low-inductance coupling is possible because of the small surface area between the power supply lines. Because of the connection of the first power supply line to the terminal pads (in the intermediate portion) and the fastening of the second power supply line within the second strip portion, it results that they are contacted, situated closely next to each other, on the conductor path layer and are thus routed away, situated closely next to each other. Here, starting from the contact point at which the power supply lines are connected to the conductor path layer, one power supply line extends toward the other (for example, the second supply line toward the first, or vice versa, or both extend toward each other) such that both supply lines extend away from the carrier with the same routing. The two supply lines may be placed on top of each other (with an insulation layer in between).

This parallel, close routing of the two power supply lines, situated next to each other, results in the low-inductance attachment. The procedure according to the invention allows the phase supply line to be routed away from the two power supply lines. Thus, starting from the contact point at which the phase supply line is connected to the conductor path layer, the phase supply line may be routed away from the power supply lines, from the contact points at which the power supply lines are connected to the conductor path layer. As a result, interference which originates from the phase supply line is only coupled to a small extent with the power supply lines, and vice versa.

In a direction along the conductor path layer (in the longitudinal direction, such as in a direction perpendicular to the direction of extent of the portions or perpendicular to the direction in which the connecting surface portions and the terminal pads alternate), the supply lines may be arranged in a row as follows: the second power supply line (which is fastened to the second strip portion), the first strip portion (which is fastened to the terminal pads or in the intermediate portion) and, subsequently, the phase supply line which is connected to the conductor path layer in the first strip portion or to surfaces connected thereto (connecting surface portions) in the intermediate portion. For example, the terminal pads allow such a sequence in which the two power supply lines follow each other, followed by the phase supply line, in order thus also to physically separate the phase supply line from the power supply lines.

The phase supply line thus extend from the conductor path layer over one side of the half-bridge module, whilst the power supply lines extend away over the opposite side of the carrier. The power supply lines, on the one hand, and the phase supply line, on the other hand, thus extend in opposite (generally in different) directions away from the carrier. No additional connecting elements are necessary to ensure that the phase supply line does not have to be arranged between the power supply lines.

One aspect is that the half-bridge module has at least a first and at least a second power supply line. The first power supply line is assigned to a negative potential, wherein the second power supply line may be assigned to a positive potential. The two potentials are potentials of a DC supply. The second supply line is connected to the second surface. The first supply line is connected to the terminal pads. The second supply line is connected to the conductor path layer at points which are located in the second strip portion, whilst the points of contact between the first supply line and the conductor path layer are located in the intermediate portion. In a direction starting from the second strip portion toward the first strip portion, the coupling point of the second supply line is therefore provided first, followed by the coupling point of the first supply line. The coupling point is here the point at which the supply line is connected to the conductor path layer. A phase supply line is routed away from the conductor path layer further in the direction and leads from the second to the first strip portion.

The region between the power supply lines is free of the phase supply line. The phase supply line extends beyond the region which is located between the phase supply lines. The terminal pads and their connection to the first supply line mean that the phase supply line does not run between the power supply lines and instead may extend away from them without crossing them.

First connectors are provided which are connected to the terminal pads and originate from them. These first connectors extend from the terminal pads into the first strip portion. For example, the first connectors extend from the terminal pads to the first surface to that part of the first surface which extends into the first strip portion. The first connectors extend from edge regions of the terminal pads which adjoin the first surface (within the first strip portion) into the first strip portion (for example, as far as transistor contact points or corresponding contact surfaces). The first connectors extend as far as populating surface regions in the first surface or in the first strip portion. Short distances result for the connectors because the terminal pads directly adjoin the first strip portion. Second connectors are provided which extend as far as populating surface regions in the second surface, starting from connection surface portions.

In the case of populated half-bridge modules, first transistors are assembled in the first strip portion, on that part of the first surface which is present in the first strip portion. The first connectors extend from the terminal pads to a contact surface or another contact element of the transistors which are located in the first strip portion. The contact surface or the contact element may be part of the transistor or may be directly connected to it. The first transistors may be present as unhoused components. This also applies to second transistors which may be assembled in the second strip portion or on or in the second surface.

The transistors may each have a first contact surface with which they are assembled on the first or second surface, or are directly electrically connected thereto in another way. The first contact surface is located on the underside of the transistors. The transistors may have second contact surfaces which are connected to connectors. The second contact surface is located on the top side of the transistors. The first connectors may be connected to the second contact surfaces of the first transistors. For example, the connectors extend from the terminal pads as far as the second contact surfaces of the transistors. The contact surfaces are assigned to electrodes of the power path of the transistors and may be assigned to the source, the drain, the collector, or the emitter of the transistor. A terminal pad may be connected (via at least one of the first connectors) to a plurality of transistors, or to only one transistor.

In the case of an unpopulated semiconductor module, populating surface regions are provided which are located in the first or second strip portion. In other words, the populating surface regions are located on the first and second surfaces. The populating surface regions are arranged in a row in the longitudinal direction or the first direction of the carrier and are spaced apart from one another. The first populating surface regions are located in the first strip portion. The transistors in the first strip portion may be arranged in one row or in a plurality of rows which extend in the first direction or longitudinal direction. One or more rows of populating surface regions which extend in the longitudinal direction or the first direction are located on a second surface. The populating surface regions are designed to be populated with transistors, for example by using SMD technology. For this purpose, they may have a populating layer, for example a metal layer for improving sintering or soldering properties, a sintered layer, or a tin-coated layer. The populating surface regions may be configured to have transistors sintered or soldered thereon.

The first surface extends in the first strip portion as a continuous surface. The first surface essentially completely covers the first strip portion. There is no electrical separation of the first surface within the first strip portion in the longitudinal direction. a continuous surface means mechanically continuous surfaces and also surfaces which are continuous in electrical terms, i.e. which have the same potential. Also included are surfaces which are divided into individual surface portions but which are directly connected to one another. Connecting surface portions extend in the intermediate portion. The latter are connected to the first surface in the first strip portion. This may be provided by electrical connecting elements. However, the connecting surface portions are parts of the first surface which extend in the intermediate portion, whilst the first surface additionally likewise extends in the first strip portion. In other words, connecting surface portions may extend away from that part of the first surface which is located within the first strip portion into the intermediate portion. The first surface thus extends in the first strip portion and moreover includes the connecting surface portions in the intermediate portion.

The connecting surface portions extend from the first to the second strip portion or adjoin them. In other words, the first surface extends as far as the second strip portion or reaches as far as the second surface (but is electrically separated therefrom). The first surface extends from the first strip portion. The connecting surface portions adjoin the second surface and the second strip portion. The connecting surface portions thus extend from the first to the second strip portion. The conductor path layer provides electrical separation between the connecting surface portions (i.e. between the first surface) and the second surface (within the second strip portion). The conductor path layer additionally provides electrical separation between the connecting surface portions (i.e. between the first surface) and the terminal pads.

The connecting surface portions and the terminal pads both extend in the intermediate portion. The terminal pads are electrically separated from the first surface and thus also from the connecting surface portions (within the conductor path layer). The terminal pads and the connecting surface portions are also electrically separated from the second surface and thus from the second strip portion within the conductor path layer. The terminal pads and the connecting surface portions are arranged alternately in the intermediate portion. The terminal pads and the connecting surface portions are here arranged in a row alternatingly or alternately in a direction which corresponds to the longitudinal direction or first direction. In each case the first strip portion, the intermediate portion, and the second strip portion extend in the first direction. The first strip portion, the intermediate portion, and the second strip portion are arranged in a row in a direction perpendicular thereto (i.e. along the width of the carrier). The connecting surface portions and the terminal pads are, however, arranged in a row in the first direction (in other words, perpendicular to the direction in which the strip portions and the intermediate portion in each case extend). This also applies for the populating surface regions of the transistors or for the transistors themselves in the case of a populated half-bridge module.

Second connectors are provided which are connected to the connecting surface portions. These second connectors extend into the second transistor strip portion. For example, the second connectors extend from the connecting surface portions into the second strip portion to populating surface regions on the second surface or as far as the second contact surfaces of transistors which are located on or in the second surface. One or more connectors lead away from the connecting surface portions. Moreover, one or more first connectors extend away from a terminal pad. A connecting surface portion may be connected to one or more second transistors via one or more second connectors. The connecting surfaces reach as far as the second surface such that the length of the second connectors may be kept very short. The first connectors may also be designed as very short because the terminal pads reach as far as the first strip portion or that part of the first surface which is located in the first strip portion. The first connectors are connected to an edge region of the terminal pads which reaches to the first strip portion or that part of the first surface which is located in the first strip portion. The second connectors are connected to the connecting surface portions at an edge region thereof which is situated opposite the second surface. The connectors may be conductors, such as bonding strips or bonding ribbons, bridge connectors or connecting elements which include pins or the like. The connectors may formed from a conductive material, such as from an aluminum or copper material.

The first power supply line is connected to the terminal pads at contact points which are situated in the intermediate portion. As a result, the first power supply line is routed in the immediate vicinity of the second power supply line which is, for example, routed so that it starts from the second surface. The phase supply line is connected to the conductor path layer at contact points which are situated in the intermediate portion or in the first transistor strip portion. In the first option, this results in approximately the same distance from the first as from the second transistors, starting from the contact points of the phase supply line. As a result, they may be coupled to the phase supply line symmetrically in terms of resistance and phase transit time. In the second option, the phase supply line is routed at a large distance from the power supply lines in order thus to avoid interference. Both options share the fact that the power supply lines may be routed away on one side, whilst the phase supply line is routed away on an opposite side. It is possible that the phase supply line does not have to be routed between the power supply lines.

Embodiments provide that the phase supply line is connected to the conductor path layer at contact points which are situated in the intermediate portion. These contact points are situated, with a deviation, centrally between a row of transistor assembly surfaces in the first transistor strip portion and a row of transistor assembly surfaces in the second transistor strip portion, wherein the deviation is no more than 20 mm, 15 mm, 10 mm, or 5 mm. In other words, the contact points at which the phase supply line is connected to the conductor path layer are situated essentially centrally between the first and second strip portions or between the assembly surfaces present there. According to the abovementioned first option, a symmetrical supply line results. In the case of a populated half-bridge module, the transistor assembly surfaces are populated with transistors. The transistor assembly surfaces correspond to the populating surface regions as mentioned above. In this approach, the phase supply line is routed away from the intermediate portion. The first power supply line is also routed away from the intermediate portion but from surfaces (specifically from the terminal pads) other than the phase supply line which extends away from the connecting surface portions, i.e. parts of the first surface which are located in the intermediate portion.

Further embodiments provide that the phase supply line is connected to the conductor path layer at first contact points which are located in the first strip portion or in the intermediate portion. The first power supply line is connected to the terminal pads at second contact points. The second power supply line is connected to the conductor path layer at third contact points. The third contact points are located in the second strip portion or on the second surface. The first contact points are located on the first surface in the region of the first surface which extends in the first strip portion.

The first and the second power supply line, and the phase supply line, in each case have discharging portions which, in the routing of the supply lines, are situated opposite the contact points. The supply lines therefore run in such a way that they start from the contact points, possibly run via further portions, and are then routed to respective discharging portions which are suitable for external coupling of the half-bridge module. The discharging portions of the power supply lines, on the one hand, and the phase supply line, on the other hand, extend away from the carrier in opposite directions. The supply lines extend away in a direction perpendicular to the first direction or to the longitudinal direction. The supply lines extend along a plane which is essentially parallel to the carrier or the conductor path layer. The supply lines extend away over the populating surface region or over the assembly surfaces. This relates to the power supply lines, wherein the first contact points may also be situated on an outer edge of the intermediate portion in such a way that they are not routed over the assembly surfaces themselves. In this case, the first contact points are provided at an outer edge region of the carrier, whilst the assembly surfaces or populating surface regions are placed closer toward the intermediate portion.

At least one row of third contact points is provided in a direction perpendicular to the first direction and along the conductor path layer. This may be followed by a row of second contact points in the intermediate portion. The first contact points are provided in the subsequent routing (perpendicular to the first direction) after the second contact points or may also be provided at the level of the second contact points. The latter is possible because the first and the second contact points are provided so that they alternate in the longitudinal direction or in the first direction, specifically alternatingly on the terminal pads and the connecting surface portions.

In the routing of the second power supply line and starting from the third contact points, a connecting portion may follow the contact points or the point at which this supply line is mechanically connected to the third contact points. Within the connecting portion and in the routing starting from the contact points, the supply line is routed away from the carrier or from the conductor path layer. A converging portion of the supply line which follows the connecting portion may likewise extend away from the carrier but may also run parallel to it or extend toward it (but not all the way). In the converging portion, the second power supply line converges with the first power supply line. In the converging portion, the second power supply line extends in a first transverse direction which is parallel to the carrier and is directed toward the intermediate portion (or to a region above it). For example, the second supply line extends in a first transverse direction which faces in the direction of a region which is provided above the second contact point. The first transverse direction thus leads to a half-space above the second contact point or above the intermediate region. Above means here that this space extends away from the carrier (starting from the conductor path layer).

Because the first power supply line starts from the intermediate portion, i.e. from contact points or from terminal pads within the intermediate portion, the second supply line approaches the first supply line by virtue of the converging portion. A smaller surface area in cross section between the power supply lines consequently results, which causes a lower inductance. Alternatively, or in combination therewith, the first power supply line may also extend from the relevant contact points (second contact points) via a converging portion in which the first power supply line extends toward the second strip portion or toward a region above the second strip portion.

In other words, the first power supply line is, for example, routed away from the carrier starting from the terminal pads initially by a first curve and then by a second curve above the second strip portion parallel to the carrier. A space results between the second strip portion and the first power supply line, inside which the second power supply line extends toward a portion of the first power supply line in which the first power supply line extends above the carrier and away therefrom. In other words, the second power supply line is initially curved toward the first supply line parallel to the carrier in order then (beyond a point at which the power supply lines merge) to be routed away at a small distance therefrom in the routing of the first supply line. The point at which the second supply line meets the first supply line (i.e. where they merge) is thus not situated above the third contact points and instead above the intermediate portion or an edge region of the second strip portion which adjoins the intermediate portion. The power supply lines are not routed above the phase supply line and also not above contact points at which the phase supply line is connected to the conductor path layer (or to the first surface).

The first and the second supply line are routed in parallel for the most part at a small distance, i.e. for example at a distance of less than 10, 5, 3, 2, or 1 mm from each other. For example, the first and the second supply line are superposed for the majority of their routing and only separated by an insulation layer. This relates also to that part of the power supply lines which results after the point at which these supply lines merge. The insulation layer includes at least one layer of lacquer and/or has a ribbon of electrically insulating material. For example, beyond the converging portion (viewed from the carrier), the first and the second power supply line run so that they are situated next to each other, i.e. are electrically insulated from each other, but so that they are situated physically close to each other (for example at a distance of less than 5, 3, 2, or 1 mm). An insulation ribbon or an insulation layer is provided between the power supply lines with a thickness of less than 10, 5, 3, 2, or 1 mm.

The phase supply line has first contact portions at which it is connected face to face to the surface of the first transistor strip portion or to the connecting surface portions. The first contact portions are connected to the first surface, for example to its connecting surface portions or to that part of the first surface which extends (continuously) in the transistor strip portion. The contact portions may be formed by a bend of the phase supply line which leads to routing of the first contact portions parallel to the first surface. The first contact portions are thus parallel to the first surface and have an underside which is connected face to face to the first surface or to the connecting surface portions or to the surface of the first transistor strip portion.

The power supply lines may also have contact portions which are routed parallel to the conductor path layer and are connected face to face to the latter. The power supply lines may also have for this purpose a bend which leads to the contact portions and which align the latter parallel to the conductor path layer. The contact portions of the power supply lines also have undersides which are connected face to face to the respective surfaces or surface portions of the conductor path layer. Two of the contact portions of the first power supply line are connected face to face to the terminal pads, i.e. to surfaces in the intermediate portion which are electrically insulated from the first surface within the conductor path layer. The second power supply line may have third contact portions at which it is connected to the second surface or to a surface within the second strip portion. The contact portions may extend in each case along the conductor path layer. For example, the conductor path portions extend within the same plane. This plane corresponds to the upper surface of the conductor path layer. The contact portions are thus connected to the same conductor path layer.

One aspect is that the second power supply line has contact portions (such as the third contact portions) at which this supply line is connected face to face to the terminal pads.

In general, the supply lines have in each case a plurality of contact portions which contact the conductor path layer at a plurality of points, wherein these contact points or contact portions may be provided for each supply line in a row which extends in the first direction or longitudinal direction. The plurality of first contact points of the phase supply line are connected to one another via the first surface. The plurality of third contact points of the second power supply line are connected to one another via the second surface. The plurality of second contact points of the first power supply line are connected to one another via this supply line itself.

The power supply lines and/or the phase supply line have in each case a plurality of contact portions which are arranged in a row in the first direction. In the case of each supply line which has a plurality of contact portions, the contact portions are (electrically) merged by the supply line itself. In other words, a plurality of contact portions of the supply line extend from a one-part portion of the supply line toward the associated contact points.

The contact portions extend in each case along the conductor path layer. The contact portions extend in a direction of extent of the supply line which is routed away from the carrier, toward the intermediate portion. Following the contact portions (in the routing of the supply line) is a connecting portion. In this connecting portion, the supply line extends away from the conductor path layer.

After connecting portions of the supply line follow the contact portions in the routing of the second power supply line, converging portions (running next to one another) or a converging portion of the supply line follow the connecting portions. This relates to the second power supply line and/or the first power supply line.

The converging portions extend in the direction of a region above the intermediate portion. The converging portion (of the second power supply line) moreover extends parallel to the conductor path layer toward the first power supply line. The converging portion here extends toward a portion of the first power supply line which extends essentially perpendicularly away from the carrier.

The converging portion is followed by a reversing curve. The direction of the routing of the supply line is reversed in the reversing curve. The reversing results in a direction which leads away from the region above the intermediate portion. The reversing curve is followed by a discharging portion (of the supply line). The discharging portion extends away from the region above the intermediate portion. Subsequently or in the subsequent routing, the discharging portion extends away from the carrier. The discharging portion is configured to be connected to an external potential-carrying conductor. The connection may be direct or may be via a discharging connector which is connected to the discharging portion. It is consequently possible that, by adapting the discharging connector, the supply line is adapted to the surrounding application in order to obtain dimensions which are specified.

The supply lines have in each case a plurality of contact portions. In each supply line, the contact portions are merged, in one of these directions of routing which lead away, to form a common portion. The supply lines thus have merging places in which the individual contact portions or the individual portions leading into them are merged to form a single portion of the supply line. These merging places are provided in a connecting portion of a supply line, in a converging portion of the supply line (such as in the case of the second power supply line), or may be provided in a reversing curve, or alternatively only in a discharging portion. The contact portions may be merged as early as in the following portion of the supply line but they may also be merged only in the converging portion or in the reversing curve or in a portion which follows a preceding portion and in which the supply line extends within a half-space above the conductor path layer away from the latter, for example essentially perpendicularly. The supply lines thus have in each case merging places, wherein, in portions in front of this merging place and which lead to the carrier, the supply line is divided or spread into a plurality of individual supply line parts (arranged next to one another), and wherein, in or after the merging place, the supply line is provided by an individual conductor, for example by a sheet-metal strip.

If the supply lines are provided as conductive strips, for example as sheet-metal strips such as metal sheets or the like, the supply lines in the portion or in the portions in which they are provided as individual conductors are then wider than in portions in which the supply line merges or is merged. In a portion in which the merging place is located, the overall width of the supply line reduces in a direction of routing which leads away from the conductor path layer.

At the contact points, the supply lines may in each case be provided as individual tongues. In the subsequent routing in which the supply line is routed away from the conductor path, these tongues are merged or are routed to form a single conductor portion above which the contact portions are merged. The merging corresponds to an electrical direct connection between the individual tongues. In the respective discharging portion, the supply lines are designed only as a single conductor (continuous across its width) which is narrower than the width that the contact tongues or contact points assume. It is consequently possible to access the individual contact tongues or contact points from above the carrier because the discharging portion situated above is narrower and does not cover the tongues, viewed from above. These tongues correspond to the contact portions of the respective supply line.

A further aspect is that the supply lines are divided in their routing into a plurality of parts, starting from the conductor path layer. One part follows the next part in the direction of routing. A physically independent discharging connector is provided which is electromechanically connected to the discharging portion. The plurality of parts are connected to one another via connecting elements, wherein the parts may, for example, be screwed to one another or be riveted, or may also be sintered, soldered, or welded to one another. By virtue of the fact that there are a plurality of parts, it is possible to geometrically adapt the coupling of the half-bridge module to external circumstances.

The supply lines and/or the connectors and/or the conductor path layer is made from an electrically conductive material, such as from a metal or an alloy, for example from copper or a copper alloy or from aluminum or an aluminum compound. The material may here take the form of a piece of sheet metal, such as a stamped piece of sheet metal. The connectors are (electrically conductively) designed for bonding or sintering or soldering or gluing; the connectors are designed for friction welding, sintering, gluing (electrically conductively), or soldering. The transistors are power transistors, for example MOSFETs or IGBTs, such as SiC power semiconductors such as SiC MOSFETs. Other power semiconductors such as diodes may also be provided on the conductor path layer, such as in combination with the transistors. The power supply lines are supply lines for two DC supply potentials of a supply voltage (DC), such as a high voltage with a nominal value of more than 60 V or at least 200 V, 400 V, 600 V, 800V, or more. The phase supply line serves for coupling to a phase of a load and may therefore also be referred to as a load supply line. An inverter module, for example a traction inverter module, has a plurality of half-bridge modules and have a plurality of phase terminals which are in each case electrically connected to a specific one of the phase supply lines. The inverter module (or also the half-bridge module) may have a heat sink surface. The carrier or carriers is or are fastened on this heat sink surface, with an underside which is situated opposite the conductor path layer. The inverter module or the half-bridge module is a power module and is designed for nominal powers of at least 10 KW, 100 KW, or 250 KW.

The carrier takes the form of a substrate or printed circuit board, for example a PCB, DCB, or IMS. The carrier may have a layer, situated opposite the conductor path layer, for heat discharge which is made from a metal material (and is electrically insulated from the conductor path layer via the insulation layer). The conductor path layer forms an outer side of the carrier and is not covered by an insulation layer of the carrier. The half-bridge module illustrated may be encapsulated (with insulation material which is not part of the carrier) and/or may be covered with an insulation layer of lacquer (which is not part of the carrier).

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

FIGS. 1 to 3 are schematic illustrations of features of the half-bridge module and are used to explain exemplary embodiments in more detail.

### DETAILED DESCRIPTION OF THE PREFERRED EMBODIMENTS

The following description of the preferred embodiment(s) is merely exemplary in nature and is in no way intended to limit the invention, its application, or uses.

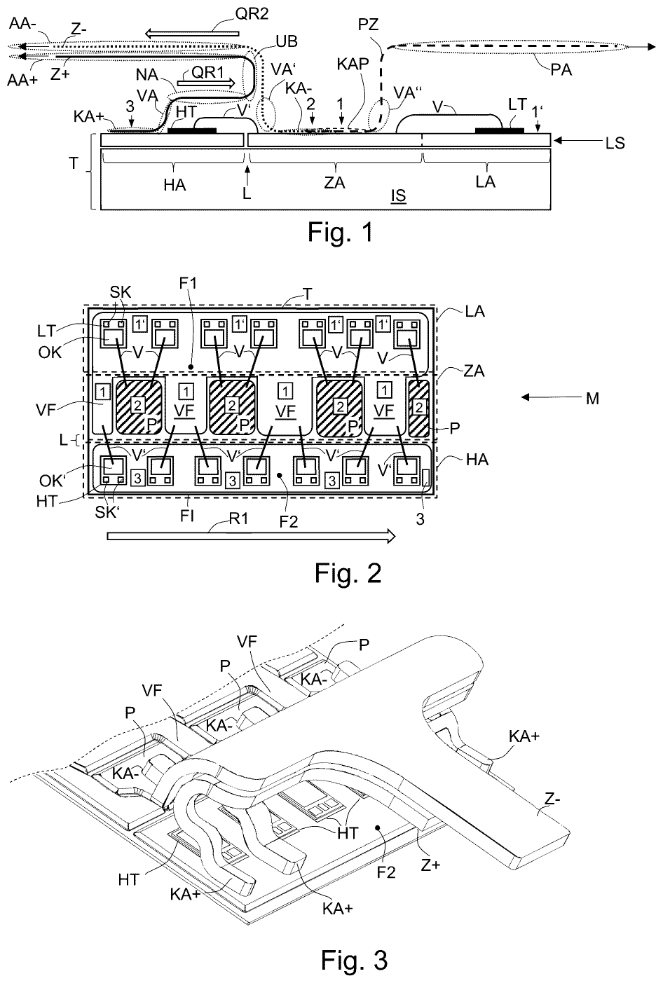

FIG. 1 is a cross section through a half-bridge module which is populated. The cross section runs along the width of the carrier T and runs perpendicularly through the carrier. The carrier T includes a conductor path layer S which is geometrically divided into a first strip portion LA, an intermediate portion ZA, and a second strip portion HA. This subdivision is used to explain in greater detail the individual functions and is a notional division which does not necessarily have an electrical correspondence. Because the strip portions may also be populated with transistors HT, LT or be provided for this purpose, the strip portions are also referred to as transistor strip portions.

Illustrated by way of example is a populated embodiment of a half-bridge module, wherein, in the case of an unpopulated half-bridge module, assembly surfaces which are formed on the upper side of the conductor path layer LS take the place of the transistors LT, HT. The intermediate portion ZA is provided between the strip portions HA, LA, wherein the portions HA, ZA are arranged in a row in this sequence (in a direction perpendicular to a longitudinal direction R1, as illustrated in FIG. 2). A first surface F1 of the conductor path layer LS is located in the strip portion LA, wherein the surface F1 is continuous perpendicular to the plane of the drawing (i.e. in the direction R1 as illustrated in FIG. 2). A second surface of the conductor path layer LS is located in the second strip portion HA, which is also illustrated in FIG. 2 as the second surface F2. This second surface F2 is separated from the intermediate portion ZA or from the surface structures embossed here (cf FIG. 2, reference signs VF and P) of the conductor path layer LS by a gap L.

A first connector V is illustrated which locates an upper side or upper contact surface of the transistor LT to a surface in the intermediate portion. This surface corresponds to the terminal pad P illustrated in FIG. 2. A second connector V′ connects a transistor HT which is located in the second strip portion HA with a surface in the intermediate portion ZA. This is a different surface in the intermediate portion ZA, specifically a part of the first surface which is also referred to as a connecting surface portion VF (see FIG. 2).

The conductor path layer LS is fastened on an insulation layer IS (which is solid). The underside of the conductor path layer LS here faces toward the insulation layer IS. Supply lines Z+, Z−, and PZ are connected to the conductor path layer LS. They are connected to the latter on the upper side of the conductor path layer LS, which side faces away from the insulation layer IS.

A first and a second power supply line Z−, Z+ is illustrated on the left-hand side above the conductor path layer LS, wherein a third supply line, specifically a phase supply line, is labeled with the reference sign PZ. It is seen that those ends of the supply lines which face away from the carrier T extend in opposite directions. The two power supply lines Z−, Z+ here extend in an opposite direction to the direction in which the phase supply line PZ extends. This relates to the discharging portions AA+, AA−, and PA. The discharging portion AA− is a portion of the first power supply line, the discharging portion AA+ is a portion of the second power supply line, and the portion PA is a discharging portion of the phase supply line PZ. The discharging portions are used for coupling to external components. The power supply lines are used for coupling to a DC supply, for example to a DC electrical system or to a battery. The phase supply line PA is used for coupling to a load or to a phase of a component, for example an electric machine.

The contact portions KA+, KA−, and KAP are illustrated in cross section in FIG. 1. They belong to the respective supply lines Z+, Z−, and PZ and form their ends which are fastened to the conductor path layer LS. As is seen, inter alia, in FIG. 2, a plurality of contact points 1, 2, and 3 at which the contact portions KA+, KA−, and KAP are fastened are located, distributed on the conductor path layer LS (or corresponding surfaces F1, F2, P or surface portions thereof such as the surface portions VF).

In the intermediate portion ZA, the terminal pads P and the connecting surface portions VF alternate, as is seen in FIG. 2. For contacting this plurality of terminal pads P and connecting surface portions VF, at least the supply lines AA−, PZ have separated conductor portions or tongues which contact the individual contact points 1, 2. The conductor portions are arranged at a distance from one another in the first direction or in the longitudinal direction (“arranged in a row” according to the individual contact points) and arranged in a row in this direction. These separated conductor portions or divided line routing may extend over the connecting portions VA−, VA2−. The separated conductor portions may extend as far as the curve by which the supply lines Z− and PZ extend again parallel to the carrier. The conductor portions may be merged in the curve; a merging place may be located within the curve. The individual conductor portions may extend as far as the discharging portions PA, AA− such that merging places are provided there.

The supply lines may therefore have a merging place or a merging point at which the conductor portions are merged to form a combined conductor. Beyond this merging point, the conductor is narrower than at the routing portions at which the individual conductor portions are present. Webs may be provided between the individual conductor portions or tongues which relate to the same supply line. The second power supply line Z+ may likewise be provided at the contact portions KA+ as a plurality of conductor portions. The latter may also be continued, separated, along the portions VA and NA, and also within the reversing curve UB. Within the reversing curve UB or at a point directly following it, merging of the individual conductor portions to form a combined conductor may be provided. Here too, webs may be provided between the conductor portions. By use of the conductor portions, the respective potentials of the supply lines Z−, Z+, and PZ may be distributed or arranged in a row in the direction R1 on the conductor path layer LS. Symmetrical coupling of the different transistors results. In the case of the coupling of the terminal pads P and the connecting surface portions VF, the merging within the supply lines (supply line Z− and PZ) additionally has an electrical function because the individual conductor portions and hence also the individual terminal pads or connecting surface portions are electrically connected to one another by the merging. This connection corresponds to a short circuit and allows the feeding of the potential of the relevant supply line to the different surfaces P and VF. Because the terminal pads P are insulated from one another, the same potential or a direct connection between the terminal pads is provided by the merging of the conductor portions in the routing of the first power supply line Z−. In the case of the connecting surface portions VF or in the case of the contact points 3 on the second surface, this merging is not absolutely necessary because it there is already a direct connection between the individual surfaces owing to the continuous routing of the second surface F2 in the second strip portion HA or the continuous routing of the first surface in the first strip portion LA. FIG. 3 shows by way of example supply lines which are divided at the conductor path layer into individual conductor portions which are located next to one another (in a row in the direction R1) and which are merged, via merging places, in each case to form a combined conductor.

FIG. 2 is a plan view of a carrier T and serves to better understand the half-bridge module described here. The carrier T is divided into three longitudinal portions or strip portions illustrated one above the other, specifically the first strip portion LA, the intermediate portion ZA, and the second strip portion HA. All three extend in the first direction R1 and are, as illustrated, arranged in a row perpendicular to the direction R1. A part of the first surface F1 is located in the first strip portion LA, wherein further connecting surface portions VF of the first surface F1 extend, separated, into the intermediate portion ZA (as far as the strip portion HA).

Transistors LT which have the surface contact OK are assembled in the strip portion LA on the first surface. They are contacted by connectors V which lead to terminal pads P which are located in the intermediate portion ZA. The intermediate portion ZA has connecting surface portions VF which belong to the first surface F1, as well as also terminal pads P which are insulated from the first surface (and also from the second surface F2). The terminal pads P extend between the two strip portions LA, HA. Connecting surface portions VF of the first surface F1 and terminal pads P alternate in the first direction R1. First contact points are located on the connecting surface portions VF. Alternatively, first contact points may be provided at the edge portion of the first strip portion LA, as designated by the reference sign 1′, wherein this edge portion includes an outer rim of the first strip portion LA. The contact points 1′ are also located that part of the first surface F1 which is located in the strip portion LA. It is illustrated that the alternative first contact points 1′ are offset essentially between the transistors LT and offset upward. The alternative first contact points 1′ are offset, with respect to the transistors LT, toward the outer edge which is situated opposite the strip portion HA.

Further transistors HT are provided in the second strip portion HA. In the same way as the transistors LT are arranged in a row in the direction R1 in the first strip portion, the transistors HT are also assembled on the second surface F2 and arranged in a row along the second strip portion HA. The transistors are in each case arranged in a row at a distance from one another in order thus not to allow any hot spot to be created. The transistors in each case also have signal contacts SK which are provided on a side of the transistors which faces that outer rim of the carrier T which is situated opposite the strip portion HA.

Second connectors V′ connect the connecting surface portions VF to surface contacts OK' of the transistors HT. By fastening the transistors on the first and second surface F1, F2, second surface contacts (on the underside of the transistors) are located directly on the first and second surfaces and are fastened thereto, for example by a soldered or sintered connection. The connectors V, V′ may be bonding strips which are produced from metal material, for example from aluminum material or copper material.

A gap L separates the surface F2, on the one hand, from the connecting surface portions VF and the terminal pads P, on the other hand, which are routed as far as the second surface. The terminal pads P are thus also separated from the second surface F2 (within the conductor path layer LS).

FIG. 1 shows that the first contact surfaces 1 (cf FIGS. 1 and 2) are connected to the phase supply line PZ. This may also apply for the contact surfaces 1′. The contact portions KAP are part of the phase supply line PZ. The contact portions KAP (cf FIG. 1) are applied face to face to the first contact points 1 or 1′ and connected thereto (for example, by a welded connection, for example a friction welded connection, by a sintered connection, by a soldered connection, or by a glued connection). Because a plurality of contact points 1 are present, specifically in each case one contact point on each intermediate portion, the phase supply line PZ has at the contact portion a plurality of separated conductor portions or tongues in the direction R1 which are then merged in the subsequent routing of the phase supply line PZ. With the merging, the phase supply line PZ narrows such that, for example after the second curve, i.e. in the discharging portion PA, the phase supply line has a smaller width than the width of all the conductor portions at the contact portion KAP (i.e. the width along which the first contact points 1, 1′ are distributed in the direction R1).

The first power supply line Z− also has a contact portion KA− in which it is divided into individual conductor portions in order to contact the individual terminal pads P and the contact surfaces 2 provided there (without effecting contact with the first surface F1 or with the second surface F2). The second contact surfaces 2 are distributed in the direction R1 such that the individual conductor portions of the supply line Z− are routed away from these second contact points 2. The conductor portions are thus arranged in a row in the longitudinal direction R1 and are spaced apart from one another in this direction. The distance between the conductor portions which contact the contact surfaces 1 and 2 is such that no contact between the potentials of the supply lines is produced.

The second power supply line Z+ is likewise equipped with separated conductor portions in order to contact the third contact surfaces 3. Here too, the conductor portions are routed essentially parallel along the conductor path layer LS and lie on the latter. Also in the second power supply line Z+, the individual conductor portions are merged in the routing of this supply line away from the contact points 3, wherein this merging is accompanied with a reduction in the width of the supply line. The width is here a dimension of the relevant supply line in the direction R1.

In the direction of extent, the supply lines Z+, Z−, and PZ have contact portions, wherein in each contact portion the relevant supply line is split up into conductor portions or tongues routed next to one another in order thus to contact a plurality of similar (i.e. belonging to the same potential) contact surfaces 1, 2, or 3. The conductor portions are merged in the routing away from the conductor layer. This is also illustrated in FIG. 3 by way of example for the supply lines Z+, Z−.

It is seen in more detail in FIG. 3 that narrowing of the supply lines owing to the merging of the conductor portions (away from the contact portions in the direction of extent) means that the individual conductor portions and contact portions (split up and routed next to one another) are accessible from above. It is seen that the contact portions KA+ and KA− extend in opposite directions. These contact portions KA+, KA− of the two power supply lines Z+, Z− enable simple fastening of the contact portions on the respective surfaces, for example by friction welding. Types of connection are thus possible in which the contact portions are fastened on the conductor path layer by processing from above.

The contact portions KA−, KA+ are, as illustrated, implemented as individual conductor portions which are merged in the subsequent routing of the supply lines Z+, Z− and in each case transition into a combined conductor. This combined conductor is present in the discharging portions AA+, AA−. It is moreover illustrated that no conductor portions or contact portions KA+ are provided below these merged power supply lines Z+, Z− or below the discharging portions in order thus to enable access from above, for example for fastening by friction welding.

Also illustrated in FIG. 3 are a plurality of second transistors HT which are located below the power supply lines Z+, Z−. It is additionally illustrated that the contact portions KA−, i.e. their individual conductor portions, are connected to the terminal pads P. It is moreover illustrated that connecting surface portions VF which belong to the first surface F1 are provided between the individual terminal pads. Lastly, it is seen that trenches, which for example completely surround the terminal pads P, are provided in the conductor path layer in order to separate the terminal pads P from the connecting surface portions VF and in order to separate the connecting surface portions and the terminal pads P from the second surface F2. This separation takes place within the conductor path layer LS and enables different potentials to be routed into the terminal pads, into the connecting surface portions VF, and in the second surface F2, all of which are provided in the same conductor path layer LS.

It is seen with the aid of the perspective illustration of FIG. 3 that the terminal pads P, the connecting surface portions VF, and the second surface F2, which represent the connecting potentials and the phase potential, are formed within the same conductor path layer. It is also seen that no additional connecting elements are necessary to produce a connection between the supply lines and the relevant potential surfaces of the conductor path layer LS.

The transistors illustrated in the Figures form, in electrical terms, a half-bridge with a high-side transistor element and a low-side transistor element. The high-side transistor element is formed by the transistors HT connected in parallel and the low-side transistor element is formed by the transistors LT connected in parallel. The connection in parallel results from the common surfaces F1 and F2 to which the transistors are connected and from the merging of the connecting surface portions VF via the first surface (in the first strip portion) and by the routing of the potentials of the terminal pads away via the same power supply line Z−. The connection point between the transistor elements of the half-bridge is illustrated from the first surface F1. The connection point or the first surface F1 is connected to the phase supply line PZ. The outer ends of the half-bridge are formed by the terminal pads P, on one hand, and the second surface F2, on the other hand. The terminal pads P here form a negative supply terminal of the half-bridge. The second surface F2 forms the positive supply terminal of the half-bridge.

The half-bridge module illustrated is designed as a power half-bridge module for power of significantly more than 10 KW and may be more than 50 KW. The half-bridge module is designed as a high-voltage half-bridge module with nominal voltages of more than 60 V and of at least 200, 400, or 800 V. The half-bridge module illustrated is used in a traction inverter of a vehicle but may also be used in a DC converter (such as on a vehicle). Other possible applications are stationary inverters and the like.

In the case of the use as a traction inverter, a plurality of phases are required such that a corresponding inverter has at least one half-bridge module per phase. In the case of a three-phase inverter, at least three half-bridge modules (with individual phase supply lines) are thus provided, wherein the power supply lines Z+, Z− are configured as combined, or are configured as individual, and are electrically connected to one another.

The half-bridge module illustrated in the Figures rests on a rectangular carrier T. The portions LA, ZA, HA illustrated may divide up the carrier T completely or may divide up a power region of the carrier T completely.

The portions LA, ZA, HA directly adjoin one another, wherein the distances illustrated in the Figures between the relevant dashed-line rectangles are provided only to better indicate the individual portions. The illustrated gap L relates to the physical separation of the second surface F2 from the terminal pads P and the power supply surface portions VF within the conductor path layer and constitutes an actual physical separation (within the conductor path layer). The carrier is designed as a printed circuit board, for example as a ceramic printed circuit board or a ceramic carrier, for example in the form of a DCB or a different carrier with at least one copper layer or a ceramic insulation layer IS. The unillustrated underside of the carrier may be connected to a heat sink, wherein the insulation layer IS is here connected to the heat sink either directly or via a thermally conductive layer, such as for example a copper layer. The illustrated carrier may moreover have a populated underside and/or have conductive intermediate layers and/or connecting elements such as vias. It should, however, be noted that all the essential connecting elements and components of the power path of the half-bridge module are located on one side of the carrier, as a result of which the conducting of current is simplified. FIG. 3 shows the very close routing enabled thereby of the power supply lines Z+, Z− in order to reduce inductive properties and moreover shows that a phase supply line is provided spaced apart from the two power supply lines Z+, Z−. In FIG. 3, a phase supply line would be able to follow in the subsequent routing in the upper left, as a result of which it is illustrated that the two power supply lines are on one side of the carrier, whilst the phase supply line is located on an opposite side of the carrier.

The description of the invention is merely exemplary in nature and, thus, variations that do not depart from the gist of the invention are intended to be within the scope of the invention. Such variations are not to be regarded as a departure from the spirit and scope of the invention.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. A half-bridge module with
a first power supply line;
a second power supply line;
a phase supply line; and
a carrier, further comprising:
a conductor path layer, further comprising:
a first transistor strip portion;
a second transistor strip portion;
an intermediate portion located between the first transistor strip portion and the second transistor strip portion, the intermediate portion having a plurality of terminal pads which are insulated peripherally in the conductor path layer;
wherein the first power supply line is connected to each of the plurality of terminal pads and is routed away therefrom, the second power supply line is connected to at least one contact point within the second transistor strip portion and is routed away therefrom, and the phase supply line is connected to at least one contact point within the intermediate portion or the first transistor strip portion and is routed away therefrom.

15. The half-bridge module of claim 14, further comprising a plurality of first connectors, each of which is connected to a corresponding one the terminal pads and extends into the first transistor strip portion.

16. The half-bridge module of claim 15, the conductor path layer further comprising:
a first surface which extends in the first transistor strip portion as a continuous surface and extends in the intermediate portion as individual connecting surface portions between the terminal pads;
wherein the connecting surface portions extend from the first transistor strip portion as far as the second transistor strip portion.

17. The half-bridge module of claim 16, further comprising a plurality of second connectors, each of which is connected to a corresponding one of the connecting surface portions and extends into the second transistor strip portion.

18. The half-bridge module of claim 14, wherein the first power supply line is connected to the terminal pads at contact points which are situated in the intermediate portion, and the phase supply line is connected to the conductor path layer at contact points which are situated in the intermediate portion or in the first transistor strip portion.

19. The half-bridge module of claim 14, wherein the phase supply line is connected to the conductor path layer at contact points which are situated in the intermediate portion, and the contact points are situated, with a deviation, centrally between a row of transistor assembly surfaces in the first transistor strip portion and a row of transistor assembly surfaces in the second transistor strip portion.

20. The half-bridge module of claim 14, further comprising:
a plurality of discharging portions, a portion of plurality of discharging portions being part of the first power supply line, a portion of the plurality of the discharging portions being part of the second power supply line, and a portion of the discharging portions being part of the phase supply line such that the portion of the plurality of discharging portions being part of the phase supply line extend away from the carrier in the opposite direction relative to the portion of plurality of discharging portions being part of the first power supply line and the portion of the plurality of the discharging portions being part of the second power supply line;
wherein the phase supply line is connected to the conductor path layer to at least one first contact point which is located in the first transistor strip portion or in the intermediate portion, the first power supply line is connected to each of the plurality of terminal pads in at least one second contact point, and the second power supply line is connected to the conductor path layer in at least one third contact point;
wherein the at least one third contact point is located in the second transistor strip portion;
wherein the portion of plurality of discharging portions being part of the first power supply line, the portion of the plurality of the discharging portions being part of the second power supply line, and the portion of the plurality of discharging portions being part of the phase supply line are situated opposite the first, second, and third contact points;

21. The half-bridge module of claim 20, the second power supply line further comprising:
a converging portion;
wherein, in the routing of the second power supply line starting from the at least one third contact point, the converging portion follows which runs toward a region above the second contact points and, beyond the converging portion, the first and the second power supply line run, situated next to each other, at least as far as the discharging portions of the first and second power supply line.

22. The half-bridge module of claim 21, the second power supply line further comprising:
a connecting portion;
wherein, in the routing of the second power supply line after the third contact points, the connecting portion follows which leads to the converging portion, and in the connecting portion the second power supply line extends away from the carrier, and in the converging portion the second power supply line extends in a first transverse direction which is essentially parallel to the carrier toward the region above the second contact point.

23. The half-bridge module of claim 14, further comprising:
a plurality of first contact portions being part of the phase supply line, each of the plurality of first contact portions connected to the surface of the first transistor strip portion or to the connecting surface portions;
a plurality of second contact portions being part of the first power supply line, each of the plurality of second contact portions connected to the terminal pads; and
a plurality of third contact portions being part of the second power supply line, each of the plurality of third contact portions it is connected to the terminal pads;
wherein each of the plurality of first contact portions, each of the plurality of second contact portions, and each of the plurality of third contact portions extend along the conductor path layer.

24. The half-bridge module of claim 23, further comprising:
a reversing curve in which the direction of extent of the second power supply line is reversed to a direction which leads away from the region above the intermediate portion; and
a discharging portion being part of the second power supply line such that the converging portion is followed by the reversing curve and the reversing curve is followed by the discharging portion, and the discharging portion extends away from the region above the intermediate portion and consequently from the carrier;
wherein each of the plurality of third contact portions extend along the conductor path layer toward the intermediate portion;
wherein in the routing of the second power supply line, the plurality of third contact portions are followed by a connecting portion of the supply line which extends away from the conductor path layer, the connecting portions are followed by a converging portion of the supply line which extends toward a region above the intermediate portion or extends parallel to the conductor path layer toward the first power supply line.

25. The half-bridge module of claim 23, wherein the phase supply line is fastened on the conductor path layer via each of the plurality of first contact portions, and each of the plurality of first contact portions are merged in a direction of extent leading away from the plurality of first contact portions to form a following corresponding connecting portion of the phase supply line.

26. The half-bridge module of claim 23, wherein the first power supply line, is fastened on the conductor path layer via each of the plurality of second contact portions, and each of the plurality of second contact portions are merged in a direction of extent leading away from the plurality of second contact portions to form a following corresponding connecting portion of the first power supply line.

27. The half-bridge module of claim 23, wherein the second power supply line is fastened on the conductor path layer each one of the plurality of third contact portions, and each of the plurality of third contact portions are merged in a direction of extent leading away from the plurality of third contact portions to form a following corresponding connecting portion of the second power supply line.

28. The half-bridge module of claim 14, wherein each of the first power supply line, second power supply line, and the phase supply line are divided in the routing starting from the conductor path layer into a plurality of parts which are connected to one another via connecting elements.
